(19) United States
(12) Patent Application Publication
(10) Pub. No.: US 2026/0100150 A1
(43) Pub. Date: Apr. 9, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: HYUNCHEOL HWANG, Yongin-si (KR); KIJU IM, Yongin-si (KR); TAE YOUNG KIM, Yongin-si (KR); HYOJUNG KIM, Yongin-si (KR); Hyesun Sung, Yongin-si (KR); Hyeong-Yun Lee, Yongin-si (KR)

(21) Appl. No.: 19/198,265

(22) Filed: May 5, 2025

(30) Foreign Application Priority Data
Oct. 8, 2024 (KR) 10-2024-0136960

(51) Int. Cl. G09G 3/00; H10H 29/32; H10H 29/39; H10H 29/49

(52) U.S. Cl. CPC G09G 3/006; H10H 29/32; H10H 29/39; H10H 29/49; G09G 2330/12

(57) ABSTRACT

A display device includes: a substrate including a display area and a test area located adjacent the display area; a pixel arranged in the display area on the substrate and including a pixel transistor and a light-emitting element connected to the pixel transistor; and a unit test element arranged in the test area on the substrate and including a test active pattern. The unit test element includes: a first test element including a test transistor which includes the test active pattern, and a first pad portion connected to the test transistor; a second test element including the test active pattern and a second pad portion and a third pad portion which are connected to the test active pattern; and a third test element including test active pattern and a fourth pad portion connected to the test active pattern. The first to third test elements share the same test active pattern.

### CROSS-REFERENCE TO RELATED APPLICATION

This U.S. patent application claims priority under 35 USC § 119 to Korean Patent Application No. 10-2024-0136960, filed on Oct. 8, 2024, in the Korean Intellectual Property Office, the disclosure of which is incorporated by reference in its entirety herein.

### 1. Technical Field

The present disclosure is generally directed to a display device. More particularly, the present disclosure is directed to a display device that perform techniques for evaluating and ensuring the performance of its display components and an electronic device including the display device.

### 2. Description of Related Art

As information technology continues to advance, display devices have become increasingly important as an interface between users and digital content.. The adoption of various types of display devices such as liquid crystal displays (LCDs), organic light emitting diode (OLED) displays, plasma display panels (PDPs) device, and quantum dot displays, has been growing.

The display device includes a pixel that emits light, and the pixel includes a pixel transistor and a light-emitting element connected to the pixel transistor. For testing the pixel transistor, the display device may include structures designed to facilitate testing, such as specific patterns or configurations tailored for measurement. These structures may be used to measure various parameters of the pixel transistor. However, variations in these structures can introduce inconsistencies in measurement results, potentially reducing the accuracy of evaluations of the pixel transistor.

### SUMMARY

Embodiments provide a display device including a test element capable of more accurately measuring element characteristics.

Embodiments provide an electronic device including the display device.

A display device according to an embodiment of the present disclosure includes: a substrate including a display area and a test area located adjacent the display area; a pixel arranged in the display area on the substrate and including a pixel transistor and a light-emitting element connected to the pixel transistor; and a unit test element arranged in the test area on the substrate and including a test active pattern. The unit test element includes: a first test element including a test transistor which includes the test active pattern, and a first pad portion which includes test pads connected to the test transistor; a second test element including a second pad portion which includes a first voltage pad, a second voltage pad, a first current pad, and a first ground pad, a third pad portion which includes a third voltage pad, a fourth voltage pad, a second current pad, and a second ground pad, and the second pad portion and the third pad portion are connected to the test active pattern; and a third test element including a fourth pad portion which includes a fifth voltage pad, a sixth voltage pad, a third current pad, and a third ground pad, and the fifth voltage pad, the sixth voltage pad, the third current pad, and the third ground pad are connected to the test active pattern.

In an embodiment, the first test element, the second test element, and the third test element may be electrically connected to each other.

In an embodiment, the pixel transistor may include a pixel active pattern, a pixel gate electrode overlapping the pixel active pattern in a plan view, a first pixel output electrode connected to the pixel active pattern, and a second pixel output electrode connected to the pixel active pattern. The test active pattern and the pixel active pattern may be arranged in a same layer as each other, and may include a same material as each other.

In an embodiment, the second pad portion, the third pad portion, the fourth pad portion, the first pixel output electrode, and the second pixel output electrode may be arranged in a same layer as each other, and may include a same material as each other.

In an embodiment, the first pad portion may include a first test pad arranged in a same layer and including a same material as the pixel gate electrode, a second test pad arranged in a same layer and including a same material as the first pixel output electrode, and a third test pad arranged in a same layer and including a same material as the second pixel output electrode.

In an embodiment, the unit test element may further include a first test pattern connected to the first test pad and overlapping the test active pattern in the plan view, a second test pattern connected to the first voltage pad and the test active pattern, a third test pattern connected to the second ground pad and the test active pattern, a fourth test pattern connected to the first current pad and the test active pattern, and a fifth test pattern connected to the fourth voltage pad and the test active pattern.

In an embodiment, the second test pattern, the third test pattern, the fourth test pattern, the fifth test pattern, the first pixel output electrode, and the second pixel output electrode may be arranged in a same layer as each other, and may include a same material as each other.

In an embodiment, the first test pattern may function as a test gate electrode of the test transistor.

In an embodiment, the second test pattern may function as a first test output electrode of the test transistor, and the third test pattern may function as a second test output electrode of the test transistor.

In an embodiment, the unit test element may further include a sixth test pattern which connects the second voltage pad and the third voltage pad.

In an embodiment, the sixth test pattern, the first pixel output electrode, and the second pixel output electrode may be arranged in a same layer as each other, and may include a same material as each other.

In an embodiment, the unit test element may further include a seventh test pattern which connects the first ground pad and the second current pad, and may overlap the sixth test pattern in the plan view. The seventh test pattern, the first pixel output electrode, and the second pixel output electrode may be arranged in a same layer as each other, and may include a same material as each other. The sixth test pattern may be arranged under the seventh test pattern.

In an embodiment, when measuring a parameter using the second test element, a first current may flow from the first current pad to the first ground pad through the fourth test pattern, the test active pattern, and the second test pattern. A second current may flow from the second voltage pad to the first voltage pad through the sixth test pattern, the third voltage pad, the third test pattern, the test active pattern, and the second test pattern.

In an embodiment, when measuring a parameter using the second test element, a first current may flow from the second current pad to the second ground pad through the second test pattern, the test active pattern, and the third test pattern. A second current may flow from the fourth voltage pad to the third voltage pad through the fifth test pattern, the test active pattern, and the third test pattern.

In an embodiment, when measuring a parameter using the third test element, a first current may flow from the third current pad to the third ground pad through the test active pattern. A second current may flow from the sixth voltage pad to the fifth voltage pad through the test active pattern.

In an embodiment, the test pads may be arranged along a first direction. The first voltage pad, the second voltage pad, the first current pad, and the first ground pad may be arranged along the first direction. The third voltage pad, the fourth voltage pad, the second current pad, and the second ground pad may be arranged along the first direction. The fifth voltage pad, the sixth voltage pad, the third current pad, and the third ground pad may be arranged along the first direction.

In an embodiment, the first test element, the second test element, and the third test element may be arranged along a second direction intersecting the first direction.

In an embodiment, the first test element, the second test element, and the third test element may be arranged along the first direction.

In an embodiment, the first to fourth pad portions may be arranged in an order of the second pad portion, the fourth pad portion, the first pad portion, and the third pad portion along the first direction.

A display device according to an embodiment of the present disclosure includes: a substrate including a display area and a test area located adjacent the display area; a pixel arranged in the display area on the substrate and including a pixel transistor and a light-emitting element connected to the pixel transistor; and a unit test element arranged in the test area on the substrate and including a test active pattern. The unit test element includes: a first test element including a test transistor which includes the test active pattern, and a first pad portion which includes test pads connected to the test transistor to enable measurement of characteristics of the pixel transistor; and a second test element including a second pad portion which includes a first voltage pad, a second voltage pad, a first current pad, and a first ground pad, a third pad portion which includes a third voltage pad, a fourth voltage pad, a second current pad, and a second ground pad, and the second pad portion and the third pad portion are connected to the test active pattern to enable measurement of a contact resistance between a pixel active pattern and a pixel output electrode of the pixel transistor.

An electronic device according to an embodiment of the present disclosure includes: a display device including a pixel; and a processor which transmits an image data signal and an input control signal to the display device. The display device includes: a substrate including a display area and a test area located adjacent the display area; the pixel arranged in the display area on the substrate and including a pixel transistor and a light-emitting element connected to the pixel transistor; and a unit test element arranged in the test area on the substrate and including a test active pattern. The unit test element includes: a first test element including a test transistor which includes the test active pattern, and a first pad portion which includes test pads connected to the test transistor; a second test element including a second pad portion which includes a first voltage pad, a second voltage pad, a first current pad, and a first ground pad, a third pad portion which includes a third voltage pad, a fourth voltage pad, a second current pad, and a second ground pad, and the second pad portion and the third pad portion are connected to the test active pattern; and a third test element including a fourth pad portion which includes a fifth voltage pad, a sixth voltage pad, a third current pad, and a third ground pad, and the fifth voltage pad, the sixth voltage pad, the third current pad, and the third ground pad are connected to the test active pattern.

A display device according to an embodiment of the present disclosure may include a unit test element arranged in a test area on a substrate and including a test active pattern, wherein the unit test element may include a first test element for testing characteristics of a pixel transistor, a second test element for measuring a contact resistance between a pixel active pattern and a pixel output electrode, and a third test element for measuring a sheet resistance of the pixel active pattern. The first test element, the second test element, and the third test element may be electrically connected to each other, and may share the same test active pattern. Accordingly, the unit test element may effectively prevent the problem that parameters measured in each test element shows different tendencies, and may more accurately measure the characteristics of the pixel transistor.

### BRIEF DESCRIPTION OF THE DRAWINGS

The above and other features of embodiments of the present inventive concept will become more apparent by describing in detailed embodiments thereof with reference to the accompanying drawings, in which:

FIG. 1 is a plan view illustrating a display device according to an embodiment of the present disclosure;

FIG. 2 is a circuit diagram illustrating a circuit structure of a pixel included in the display device of FIG. 1;

FIG. 3 is a cross-sectional view taken along line I-I′ of FIG. 1;

FIG. 4 is a plan view illustrating a test area of FIG. 1 according to an embodiment of the present disclosure;

FIG. 5 is a plan view illustrating a unit test element included in the display device of FIG. 1 according to an embodiment of the present disclosure;

FIGS. 6, 7, 8, and 9 are plan views for describing a method of measuring parameters by the unit test element of FIG. 5 according to an embodiment of the present disclosure;

FIG. 10 is a plan view illustrating a display device according to an embodiment of the present disclosure;

FIG. 11 is a plan view illustrating a test area of FIG. 10 according to an embodiment of the present disclosure;

FIG. 12 is a plan view illustrating a unit test element included in the display device of FIG. 10 according to an embodiment of the present disclosure;

FIGS. 13, 14, 15, and 16 are plan views for describing a method of measuring parameters by the unit test element of FIG. 12 according to an embodiment of the present disclosure;

FIG. 17 is a block diagram of an electronic device according to an embodiment of the present disclosure;

FIG. 18 is a schematic diagram of an electronic device according to various embodiments; and

FIG. 19 is a block diagram of an electronic device according to an embodiment of the present disclosure.

### DETAILED DESCRIPTION

Hereinafter, embodiments of the present disclosure will be described in detail with reference to the accompanying drawings. The same reference numerals are used for the same components in the drawings, and redundant descriptions of the same components will be omitted.

At least one embodiment of the present disclosure relates to a display device that includes a unit test element for accurately evaluating the electrical characteristics of a pixel transistor of the display device. The unit test element integrates at least two test elements, a first test element for testing the characteristics of the pixel transistor and a second test element for measuring contact resistance between a pixel active pattern and a pixel output electrode of the pixel transistor. By sharing a common test active pattern, these two test elements ensure that measurements are conducted under identical conditions, eliminating inconsistencies caused by variations in separate test structures. This results in more accurate transistor evaluations, increasing the reliability of display device manufacturing.

In some embodiments, the unit test element further includes a third test element designed to measure sheet resistance of the pixel active pattern. When all three test elements are present, they are electrically connected and share the same test active pattern, ensuring uniform measurement conditions across all tests. This expanded configuration allows for a comprehensive assessment of pixel transistor performance while still maintaining measurement consistency.

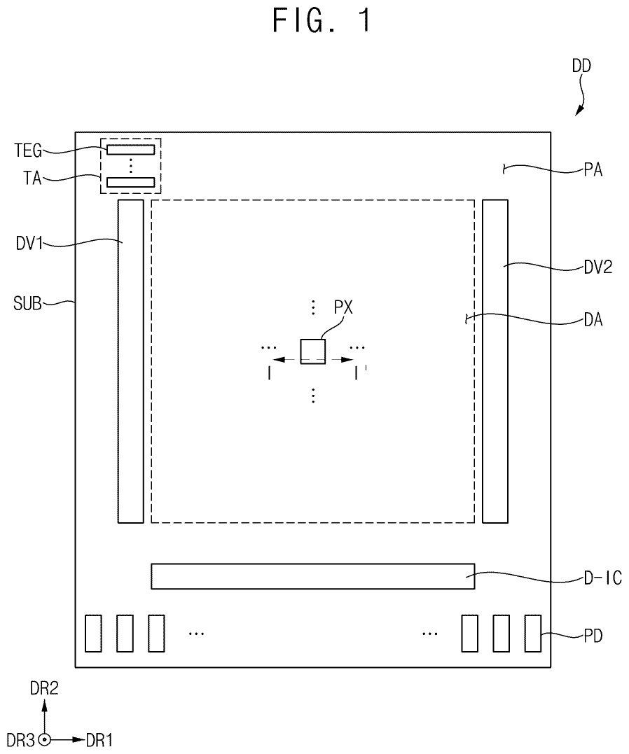

FIG. 1 is a plan view illustrating a display device according to an embodiment of the present disclosure.

In this specification, a plane may be defined by a first direction DR1 and a second direction DR2 intersecting the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2. As used herein the “plan view”is a view in the third direction DR3.

Referring to FIG. 1, the display device DD according to an embodiment of the present disclosure may include a substrate SUB, pixels PX, unit test elements TEG, a first gate driver DV1 (e.g., a first driver circuit), a second gate driver DV2 (e.g., a second driver circuit), a driving chip D-IC, and pads PD.

For example, the display device DD may have a rectangular planar shape. In an embodiment, the display device DD may have a rectangular planar shape having a short side extending in the first direction DR1 and a long side extending in the second direction DR2. However, the present disclosure is not limited thereto, and the planar shape of the display device DD may be varied according to various embodiments.

The substrate SUB may include a display area DA and a peripheral area PA. The display area DA may be defined as an area that displays an image by generating light or adjusting the transmittance of light provided from an external light source. The pixels PX may be arranged in the display area DA. Each of the pixels PX may generate light in response to a driving signal. For example, the pixels PX may be arranged in a matrix form along the first direction DR1 and the second direction DR2.

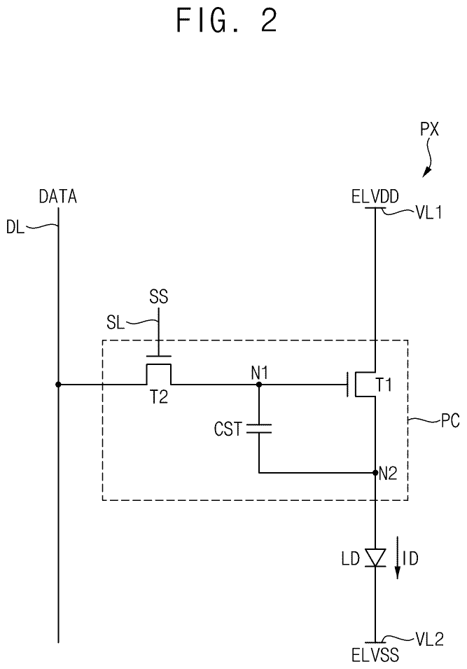

Lines connected to the pixels PX may be arranged in the display area DA. For example, the lines may include data lines (DL, refer to FIG. 2) connected to the pixels PX to provide a data voltage and gate or scan lines (SL, refer to FIG. 2) connected to the pixels PX to provide a gate signal. For example, each of the data lines may extend in the second direction DR2, and each of the gate lines may extend in the first direction DR1.

The peripheral area PA may be located around the display area DA. The peripheral area PA may surround at least a portion of the display area DA in a plan view. For example, the peripheral area PA may entirely surround the display area DA in a plan view. The peripheral area PA should not display an image.

In an embodiment, the peripheral area PA includes a test area TA. For example, the test area TA may be adjacent to an upper side of the display area DA, but the present disclosure is not limited thereto. For example, the test area TA may be positioned near the upper edge of the display area DA.

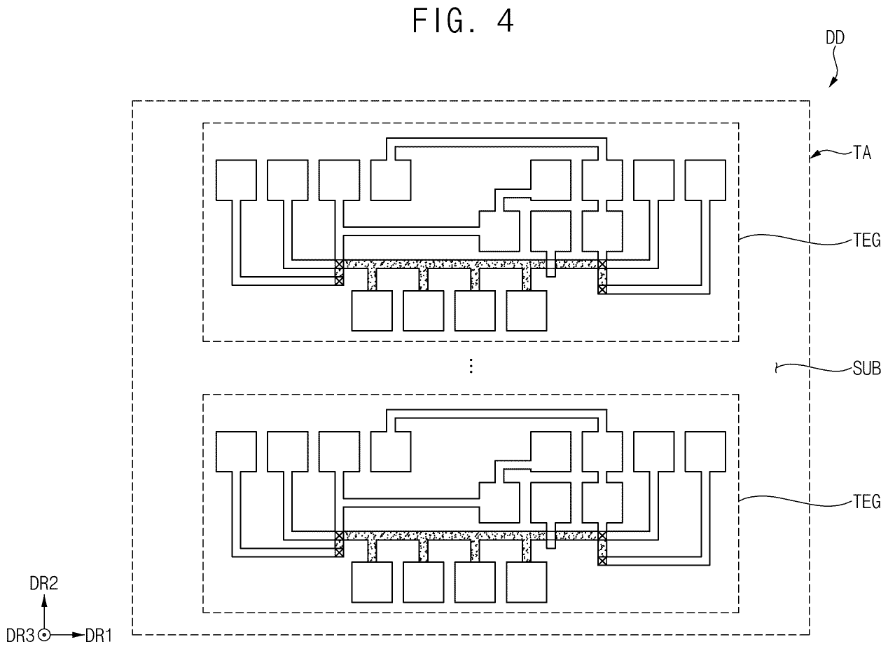

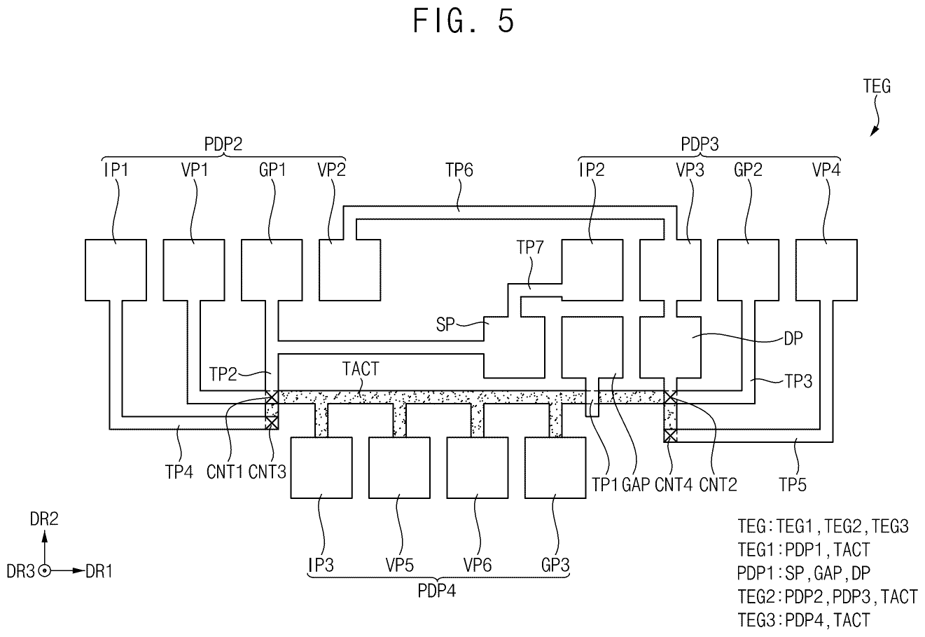

Several unit test elements TEG may be arranged in the test area TA on the substrate SUB. Each of the unit test elements TEG is configured to facilitate measurement of characteristics of an element included in the display device DD. In an embodiment, each of the unit test elements TEG includes a first test element (TEG1, refer to FIG. 5) for testing characteristics of a pixel transistor and a second test element (TEG2, refer to FIG. 5) for measuring a contact resistance between a pixel active pattern and an electrode of the pixel transistor. In a further embodiment, in addition to the first and second test elements, a third test element (TEG3, refer to FIG. 5) is present for measuring a sheet resistance of the pixel active pattern of the pixel transistor. A detailed description thereof will be described below with reference to FIGS. 4 to 9.

The first gate driver DV1 and the second gate driver DV2 may be arranged in the peripheral area PA on the substrate SUB. For example, the first gate driver DV1 may be arranged in the peripheral area PA adjacent to a left side of the display area DA, and the second gate driver DV2 may be arranged in the peripheral area PA adjacent to a right side of the display area DA. The first gate driver DV1 and the second gate driver DV2 may provide the gate signal to the pixels PX through the gate lines. In an embodiment, one of the first gate driver DV1 and the second gate driver DV2 is omitted.

The driving chip D-IC and the pads PD may be arranged in the peripheral area PA on the substrate SUB. The driving chip D-IC and the pads PD may be arranged in the peripheral area PA adjacent to a lower side of the display area DA. The driving chip D-IC may be connected to the pads PD through an anisotropic conductive film. The driving chip D-IC may provide a driving signal to the pixels PX. The driving signal may include various signals for driving the pixels PX, such as a driving voltage or a data voltage. The driving signal may be transmitted to the pixels PX through the pads PD. For example, the driving chip D-IC may be a data driver.

FIG. 2 is a circuit diagram illustrating a circuit structure of a pixel included in the display device of FIG. 1.

Referring to FIG. 2, each of the pixels PX may include a light-emitting element LD and a pixel driving circuit PC connected to the light-emitting element LD. In an embodiment, the pixel driving circuit PC includes a first transistor T1, a second transistor T2, and a storage capacitor CST. In FIG. 2, both the first transistor T1 and the second transistor T2 are illustrated as n-type transistors, but the present disclosure is not limited thereto. One of the first transistor T1 and the second transistor T2 may be the n-type transistor, and the other may be a p-type transistor. For example, the first transistor T1 may be the n-type transistor and the second transistor T2 may be the p-type transistor.

When the pixel PX includes the n-type transistor and the p-type transistor, an active pattern of the n-type transistor may include an oxide semiconductor material, and an active pattern of the p-type transistor may include a silicon semiconductor material. However, the present disclosure is not limited thereto, and both the active pattern of the n-type transistor and the active pattern of the p-type transistor may include a silicon semiconductor material.

The pixel driving circuit PC may be connected to a gate line SL, a data line DL, a first voltage line VL1, and a second voltage line VL2. The gate line SL may transmit a gate signal SS. The data line DL may transmit a data voltage DATA. The first voltage line VL1 may transmit a driving voltage ELVDD having a relatively high voltage level. The second voltage line VL2 may transmit a common voltage ELVSS having a relatively low voltage level.

The first transistor T1 may include a gate terminal, a first terminal, and a second terminal. The gate terminal of the first transistor T1 may be connected to a first node N1. The first terminal of the first transistor T1 may receive the driving voltage ELVDD through the first voltage line VL1. The second terminal of the first transistor T1 may be connected to a second node N2. The first transistor T1 may provide a driving current ID to the light-emitting element LD.

The second transistor T2 may include a gate terminal, a first terminal, and a second terminal. The gate terminal of the second transistor T2 may receive the gate signal SS through the gate line SL. The first terminal of the second transistor T2 may receive the data voltage DATA through the data line DL. The second terminal of the second transistor T2 may be connected to the first node N1. The second transistor T2 may be turned on or turned off in response to the gate signal SS. While the second transistor T2 is turned on, the second terminal of the second transistor T2 may provide the data voltage DATA to the first node N1. Accordingly, the second transistor T2 may drive the first transistor T1.

The storage capacitor CST may include a first terminal and a second terminal. The first terminal of the storage capacitor CST may be connected to the first node N1. The second terminal of the storage capacitor CST may be connected to the second node N2. The storage capacitor CST may be charged and discharged according to the data voltage DATA transmitted to the first node N1.

The light-emitting element LD may include an anode and a cathode. The anode of the light-emitting element LD may be connected to the second node N2. The cathode of the light-emitting element LD may receive the common voltage ELVSS through the second voltage line VL2. The light-emitting element LD may generate light having a luminance corresponding to the driving current ID.

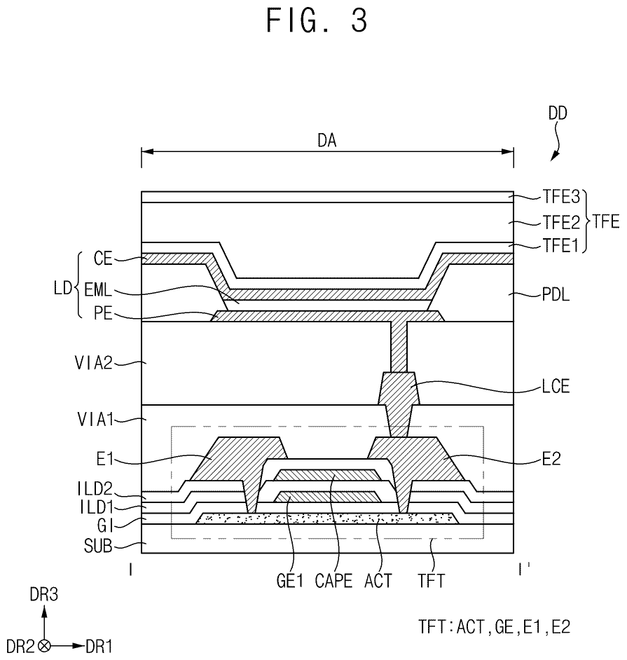

FIG. 3 is a cross-sectional view taken along line I-I′ of FIG. 1.

Referring to FIG. 3, the display device DD may include a substrate SUB, a pixel transistor TFT, a gate insulating layer GI, a first inter-layer insulating layer ILD1, a second inter-layer insulating layer ILD2, a capacitor electrode CAPE, a first via-insulating layer VIA1, a light-emitting element connection electrode LCE, a second via-insulating layer VIA2, the light-emitting element LD, a pixel defining layer PDL, and an encapsulation layer TFE.

The pixel transistor TFT may include a pixel active pattern ACT, a pixel gate electrode GE, a first pixel output electrode E1, and a second pixel output electrode E2. The light-emitting element LD may include a pixel electrode PE, a light-emitting layer EML, and a common electrode CE.

The substrate SUB may include a transparent material or an opaque material. The substrate SUB may be formed of a transparent resin substrate. A polyimide substrate is an example of the transparent resin substrate. In an embodiment, the polyimide substrate includes a first organic layer, a first barrier layer and a second organic layer. In an embodiment, the substrate SUB includes a quartz substrate (e.g., a synthetic quartz substrate or a fluorine-doped quartz substrate), a calcium fluoride substrate, a soda-lime glass substrate or a non-alkali glass substrate. These may be used alone or in combination with each other.

A buffer layer may be arranged on the substrate SUB. The buffer layer may prevent diffusion of metal atoms or impurities from the substrate SUB to an upper structure (e.g., the pixel transistor TFT, the light-emitting element LD, etc.). In addition, the buffer layer may serve to improve flatness of a surface of the substrate SUB when the surface of the substrate SUB is not uniform. For example, the buffer layer may include an organic insulating material or an inorganic insulating material. In an embodiment, the buffer layer is omitted.

The pixel active pattern ACT may be arranged on the substrate SUB. The pixel active pattern ACT may include a semiconductor material. For example, the pixel active pattern ACT may include a silicon semiconductor material, an oxide semiconductor material, an organic semiconductor material, or the like. The silicon semiconductor material may include amorphous silicon or polycrystalline silicon. The oxide semiconductor material may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn).

The gate insulating layer GI may be arranged on the substrate SUB and the pixel active pattern ACT. The gate insulating layer GI may cover the pixel active pattern ACT on the substrate SUB and may be arranged along the profile of the pixel active pattern ACT with a substantially uniform thickness. The gate insulating layer GI may include an inorganic insulating material. Examples of the inorganic insulating material that may be used as the gate insulating layer GI may include silicon oxide (SiOₓ), silicon nitride (SiNₓ) or silicon oxynitride (SiOₓN_{y}). These may be used alone or in combination with each other.

The pixel gate electrode GE may be arranged on the gate insulating layer GI. The pixel gate electrode GE may overlap the pixel active pattern ACT in a plan view. The pixel gate electrode GE may include a metal, an alloy, a conductive metal nitride, a conductive metal oxide or a transparent conductive oxide. Examples of a conductive material that may be used as the pixel gate electrode GE include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO) or indium zinc oxide (IZO). These may be used alone or in combination with each other.

The first inter-layer insulating layer ILD1 may be arranged on the gate insulating layer GI. For example, the first inter-layer insulating layer ILD1 may cover the pixel gate electrode GE on the gate insulating layer GI and may be arranged along the profile of the pixel gate electrode GE with a substantially uniform thickness. The first inter-layer insulating layer ILD1 may include an inorganic insulating material. Examples of the inorganic insulating material that may be used as the first inter-layer insulating layer ILD1 include silicon oxide (SiOₓ) or silicon nitride (SiNₓ), silicon oxynitride (SiOₓN_{y}). These may be used alone or in combination with each other.

The capacitor electrode CAPE may be arranged on the first inter-layer insulating layer ILD1. The capacitor electrode CAPE may overlap the pixel gate electrode GE in a plan view. The capacitor electrode CAPE may form the storage capacitor (CST, refer to FIG. 2) together with the pixel gate electrode GE. The capacitor electrode CAPE may include a metal, an alloy, a conductive metal oxide, a conductive metal nitride or a transparent conductive oxide. These may be used alone or in combination with each other.

The second inter-layer insulating layer ILD2 may be arranged on the first inter-layer insulating layer ILD1. For example, the second inter-layer insulating layer ILD2 may cover the capacitor electrode CAPE on the first inter-layer insulating layer ILD1, and may be arranged along the profile of the capacitor electrode CAPE with a substantially uniform thickness. The second inter-layer insulating layer ILD2 may include an inorganic insulating material. Examples of the inorganic insulating material that may be used as the second inter-layer insulating layer ILD2 include silicon oxide (SiOₓ), silicon nitride (SiNₓ) or silicon oxynitride (SiOₓN_{y}). These may be used alone or in combination with each other.

The first pixel output electrode E1 and the second pixel output electrode E2 may be arranged on the second inter-layer insulating layer ILD2. The first pixel output electrode E1 may be connected to the pixel active pattern ACT through a contact hole that penetrates the gate insulating layer GI, the first inter-layer insulating layer ILD1, and the second inter-layer insulating layer ILD2. The second pixel output electrode E2 may be connected to the pixel active pattern ACT through a contact hole that penetrates the gate insulating layer GI, the first inter-layer insulating layer ILD1, and the second inter-layer insulating layer ILD2.

Accordingly, the pixel transistor TFT including the pixel active pattern ACT, the pixel gate electrode GE, the first pixel output electrode E1, and the second pixel output electrode E2 may be formed on the substrate SUB. For example, the pixel transistor TFT may correspond to the first transistor T1 of FIG. 2. That is, the pixel gate electrode GE may correspond to the gate terminal of the first transistor T1. The first pixel output electrode E1 and the second pixel output electrode E2 may correspond to the first terminal and the second terminal of the first transistor T1.

The first via-insulating layer VIA1 may be arranged on the second inter-layer insulating layer ILD2. For example, the first via-insulating layer VIA1 may sufficiently cover the first pixel output electrode E1 and the second pixel output electrode E2 on the second inter-layer insulating layer ILD2, and may have a substantially flat upper surface. The first via-insulating layer VIA1 may include an organic insulating material. Examples of the organic insulating material that may be used as the first via-insulating layer VIA1 include a polyacryl-based resin, a polyimide-based resin, a polyamide-based resin, a siloxane-based resin, an acryl-based resin, an epoxy-based resin, or the like. These may be used alone or in combination with each other.

The light-emitting element connection electrode LCE may be arranged on the first via-insulating layer VIA1. The light-emitting element connection electrode LCE may be connected to the first pixel output electrode E1 or the second pixel output electrode E2 through a contact hole that penetrates the first via-insulating layer VIA1. Accordingly, the light-emitting element connection electrode LCE may electrically connect the pixel transistor TFT and the light-emitting element LD. The light-emitting element connection electrode LCE may include a metal, an alloy, a conductive metal oxide, a conductive metal nitride, a transparent conductive oxide, or the like. These may be used alone or in combination with each other.

The second via-insulating layer VIA2 may be arranged on the first via-insulating layer VIA1. For example, the second via-insulating layer VIA2 may sufficiently cover the light-emitting element connection electrodes LCE on the first via-insulating layer VIA1, and may have a substantially flat upper surface. The second via-insulating layer VIA2 may include an organic insulating material. Examples of the organic insulating material that may be used as the second via-insulating layer VIA2 include a polyacryl-based resin, a polyimide-based resin, a polyamide-based resin, a siloxane-based resin, an acryl-based resin or an epoxy-based resin. These may be used alone or in combination with each other.

The pixel electrode PE may be arranged on the second via-insulating layer VIA2. The pixel electrode PE may be connected to the light-emitting element connection electrode LCE through a contact hole that penetrates the second via-insulating layer VIA2. The pixel electrode PE may include a metal, an alloy, a conductive metal oxide, a conductive metal nitride or a transparent conductive oxide. These may be used alone or in combination with each other. For example, the pixel electrode PE may function as the anode of the light-emitting element LD of FIG. 2.

The pixel defining layer PDL may be arranged on the second via-insulating layer VIA2. The pixel defining layer PDL may cover an edge of the pixel electrode PE, and may expose an upper surface of the pixel electrode PE. The pixel defining layer PDL may include an organic insulating material and/or an inorganic insulating material. Examples of the organic insulating material that may be used as the pixel defining layer PDL include polyacryl-based resin, polyimide-based resin, polyamide-based resin, siloxane-based resin, acryl-based resin or epoxy-based resin. These may be used alone or in combination with each other.

The light-emitting layer EML may be arranged on the pixel electrode PE. The light-emitting layer EML may emit light having a specific color (e.g., red, green, or blue). In an embodiment, the light-emitting layer EML may include at least one of an organic light-emitting material and a quantum dot. For example, the light-emitting layer EML may have a single-layer structure including one light-emitting structure, but the present disclosure is not limited thereto. The light-emitting layer EML may also have a tandem structure including a plurality of light-emitting structures.

The common electrode CE may be arranged on the pixel defining layer PDL and the light-emitting layer EML. The common electrode CE may cover the pixel defining layer PDL and the light-emitting layer EML, and may be arranged along the profiles of the pixel defining layer PDL and the light-emitting layer EML with a substantially uniform thickness. The common electrode CE may include a metal, an alloy, a conductive metal oxide, a conductive metal nitride or a transparent conductive oxide. These may be used alone or in combination with each other. For example, the common electrode CE may function as the cathode of the light-emitting element of FIG. 2.

Accordingly, the light-emitting element LD including the pixel electrode PE, the light-emitting layer EML, and the common electrode CE may be formed on the second via-insulating layer VIA2.

The encapsulation layer TFE may be arranged on the common electrode CE. The encapsulation layer TFE may prevent impurities, moisture, or the like from penetrating into the light-emitting element LD from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ) or silicon oxynitride (SiOₓN_{y}). These may be used alone or in combination with each other. For example, the organic encapsulation layer may include a polymer cured material such as polyacrylate. In an embodiment, the encapsulation layer TFE may include a first inorganic encapsulation layer TFE1, an organic encapsulation layer TFE2, and a second inorganic encapsulation layer TFE3.

The first inorganic encapsulation layer TFE1 may be arranged on the common electrode CE. The first inorganic encapsulation layer TFE1 may cover the common electrode CE and may be arranged along the profile of the common electrode CE with a substantially uniform thickness. The first inorganic encapsulation layer TFE1 may prevent the light-emitting element LD from being deteriorated due to penetration of impurities, moisture, etc. In addition, the first inorganic encapsulation layer TFE1 may protect the light-emitting element LD from an external impact. For example, the first inorganic encapsulation layer TFE1 may include an inorganic insulating material having flexibility. For example, the first inorganic encapsulation layer TFE1 may be composed of a flexible inorganic insulating material.

The organic encapsulation layer TFE2 may be arranged on the first inorganic encapsulation layer TFE1. The organic encapsulation layer TFE2 may flatten a step difference of the first inorganic encapsulation layer TFE1. For example, the organic encapsulation layer TFE2 may serve to even out surface irregularities or height variations present in the first inorganic encapsulation layer TFE1. Accordingly, the organic encapsulation layer TFE2 may have a substantially flat upper surface. The organic encapsulation layer TFE2 may protect the light-emitting element LD from external impact together with the first inorganic encapsulation layer TFE1. For example, the organic encapsulation layer TFE2 may include an organic material having flexibility.

The second inorganic encapsulation layer TFE3 may be arranged on the organic encapsulation layer TFE2. The second inorganic encapsulation layer TFE3 may prevent the light-emitting element LD from being deteriorated due to penetration of impurities, moisture, etc. together with the first inorganic encapsulation layer TFE1. In addition, the second inorganic encapsulation layer TFE3 may protect the light-emitting element LD from external impact together with the first inorganic encapsulation layer TFE1 and the organic encapsulation layer TFE2. For example, the second inorganic encapsulation layer TFE3 may include an inorganic insulating material having flexibility. For example, the second inorganic encapsulation layer TFE3 may be composed of a flexible inorganic insulating material.

Although the display device DD of the present disclosure with respect to an organic light emitting diode (OLED) display device, the configuration of the present disclosure is not limited thereto. In other embodiments, the display device DD may include a liquid crystal display (LCD) device, a field emission display (FED) device, a plasma display panel (PDP) device, an electrophoretic image display (EPD) device, an inorganic light emitting diode (ILED) display device, or a quantum dot display device.

FIG. 4 is a plan view illustrating the test area of FIG. 1 according to an embodiment. FIG. 5 is a plan view illustrating a unit test element of the test area included in the display device of FIG. 1 according to an embodiment.

Referring to FIGS. 3, 4, and 5, the unit test elements TEG may be arranged in the test area TA on the substrate SUB. For example, the unit test elements TEG may be arranged along the second direction DR2. For example, the unit test elements TEG may be spaced apart from one another in the second direction DR2. However, the present disclosure is not limited thereto, and the unit test elements TEG may be arranged along the first direction DR1.

As illustrated in FIG. 5, in an embodiment, each of the unit test elements TEG include a first test element TEG1 and a second test element TEG2 that are electrically connected to each other. In a further embodiment, each of the unit test elements TEG additional includes a third test element TEG3 that is electrically connected to the first test element TEG1 and the second test element TEG2. In an embodiment, the first test element TEG1, the second test element TEG2, and the third test element TEG3 may be arranged along the second direction DR2. However, the present disclosure is not limited thereto, and the planar shape on which the first to third test elements TEG1, TEG2, and TEG3 included in the unit test element TEG are arranged may be varied according to embodiments.

Each of the unit test elements TEG may further include first to seventh test patterns TP1, TP2, TP3, TP4, TP5, TP6, and TP7. In an embodiment, the second to seventh test patterns TP2, TP3, TP4, TP5, TP6, and TP7, the first pixel output electrode E1, and the second pixel output electrode E2 are arranged on the same layer as each other, and may include the same material as each other.

The first test element TEG1 may include a test transistor including a test active pattern TACT and a first pad portion PDP1 connected to the test transistor.

The first pad portion PDP1 may include a first test pad GAP, a second test pad SP, and a third test pad DP. In an embodiment, the first pad portion PDP1 may be arranged along the first direction DR1. For example, the first pad portion PDP1 may be arranged in an order of the second test pad SP, the first test pad GAP, and the third test pad DP along the first direction DR1. However, the present disclosure is not limited thereto.

In an embodiment, the first test pad GAP and the pixel gate electrode GE are arranged on the same layer as each other, and may include the same material as each other. In an embodiment, the second test pad SP and the first pixel output electrode E1 are arranged on the same layer as each other, and may include the same material as each other. In an embodiment, the third test pad DP and the second pixel output electrode E2 are arranged on the same layer as each other, and may include the same material as each other.

The first test pattern TP1 may be connected to the first test pad GAP. In an embodiment, the first test pattern TP1, the first test pad GAP, and the pixel gate electrode GE are arranged in the same layer as each other, and may include the same material as each other. The first test pattern TP1 may overlap the test active pattern TACT in a plan view. In an embodiment, the first test pattern TP1 functions as a test gate electrode of the test transistor. The test transistor is separate from the pixel transistor, does not perform a display function, and is used to evaluate the pixel transistor.

The second test pattern TP2 may be connected to the second test pad SP. In an embodiment, the second test pattern TP2, the second test pad SP, and the first pixel output electrode E1 are arranged on the same layer as each other, and may include the same material as each other. The second test pattern TP2 may contact the test active pattern TACT through a first contact hole CNT1. In an embodiment, the second test pattern TP2 may function as a first test output electrode of the test transistor.

The third test pattern TP3 may be connected to the third test pad DP. In an embodiment, the third test pattern TP3, the third test pad DP, and the second pixel output electrode E2 are arranged in the same layer as each other, and may include the same material as each other. The third test pattern TP3 may contact the test active pattern TACT through a second contact hole CNT2. In an embodiment, the third test pattern TP3 may function as a second test output electrode of the test transistor.

The test transistor may have a same layered structure as the pixel transistor TFT. In an embodiment, the gate electrode (or, the first test pattern TP1) of the test transistor and the pixel gate electrode GE are arranged in the same layer as each other, and may include the same material as each other. In an embodiment, the first test output electrode (or, the second test pattern TP2) of the test transistor and the first pixel output electrode E1 are arranged in the same layer as each other, and may include the same material as each other. In an embodiment, the second test output electrode (or, the third test pattern TP3) of the test transistor and the second pixel output electrode E2 are arranged in the same layer as each other, and may include the same material as each other.

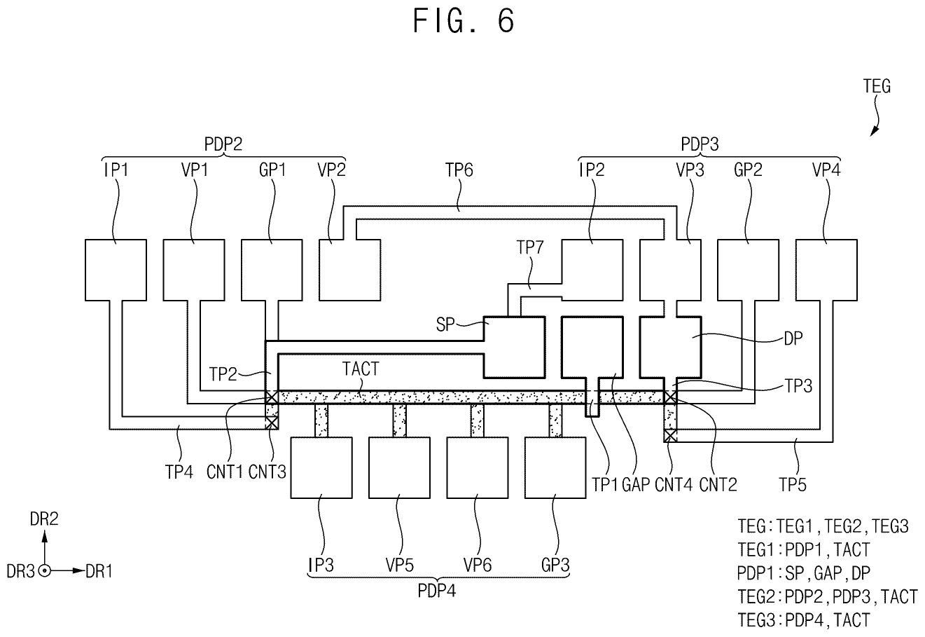

The first test element TEG1 facilitates the measurement of the characteristics of the pixel transistor TFT by providing a test structure that allows external testing equipment to evaluate its electrical properties. A method of testing the characteristics of the pixel transistor TFT using the first test element TEG1 will be described below with reference to FIG. 6.

The second test element TEG2 may include a second pad portion PDP2, a third pad portion PDP3, and the test active pattern TACT that connects the second pad portion PDP2 and the third pad portion PDP3.

The second pad portion PDP2 may include a first voltage pad VP1, a second voltage pad VP2, a first current pad IP1, and a first ground pad GP1. In an embodiment, the second pad portion PDP2 is arranged along the first direction DR1. For example, the second pad portion PDP2 may be arranged in an order of the first current pad IP1, the first voltage pad VP1, the first ground pad GP1, and the second voltage pad VP2 along the first direction DR1. However, the present disclosure is not limited thereto.

In an embodiment, the second pad portion PDP2, the first pixel output electrode E1, and the second pixel output electrode E2 are arranged in the same layer as each other, and may include the same material as each other. That is, the first voltage pad VP1, the second voltage pad VP2, the first current pad IP1, the first ground pad GP1, the first pixel output electrode E1, and the second pixel output electrode E2 may be arranged in the same layer as each other, and may include the same material as each other.

The second test pattern TP2 may be connected to the first voltage pad VP1 and the first ground pad GP1. That is, the second test pattern TP2, which functions as the first test output electrode of the test transistor, may be connected to the first voltage pad VP1 and the first ground pad GP1.

The fourth test pattern TP4 may be connected to the first current pad IP1. In an embodiment, the fourth test pattern TP4 and the first current pad IP1 are arranged in the same layer as each other, and may include the same material as each other. The fourth test pattern TP4 may contact the test active pattern TACT through a third contact hole CNT3.

The third pad portion PDP3 may include a third voltage pad VP3, a fourth voltage pad VP4, a second current pad IP2, and a second ground pad GP2. In an embodiment, the third pad portion PDP3 is arranged along the first direction DR1. For example, the third pad portion PDP3 may be arranged in an order of the second current pad IP2, the third voltage pad VP3, the second ground pad GP2, and the fourth voltage pad VP4 along the first direction DR1. However, the present disclosure is not limited thereto.

In an embodiment, the third pad portion PDP3, the first pixel output electrode E1, and the second pixel output electrode E2 are arranged in the same layer as each other, and may include the same material as each other. That is, the third voltage pad VP3, the fourth voltage pad VP4, the second current pad IP2, the second ground pad GP2, the first pixel output electrode E1, and the second pixel output electrode E2 may be arranged in the same layer as each other, and may include the same material as each other.

The third test pattern TP3 may be connected to the second ground pad GP2. That is, the third test pattern TP3, which functions as the second test output electrode of the test transistor, may be connected to the second ground pad GP2. In addition, the third voltage pad VP3 may be connected to the third test pad DP.

The fifth test pattern TP5 may be connected to the fourth voltage pad VP4. In an embodiment, the fifth test pattern TP5 and the fourth voltage pad VP4 are arranged in the same layer as each other, and may include the same material as each other. The fifth test pattern TP5 may contact the test active pattern TACT through a fourth contact hole CNT4.

In an embodiment, the sixth test pattern TP6 may connect the second voltage pad VP2 of the second pad portion PDP2 and the third voltage pad VP3 of the third pad portion PDP3. In an embodiment, the sixth test pattern TP6, the first pixel output electrode E1, and the second pixel output electrode E2 are arranged in the same layer as each other, and may include the same material as each other. However, the present disclosure is not limited thereto.

In an embodiment, the seventh test pattern TP7 may connect the second current pad IP2 and the second test pad SP.

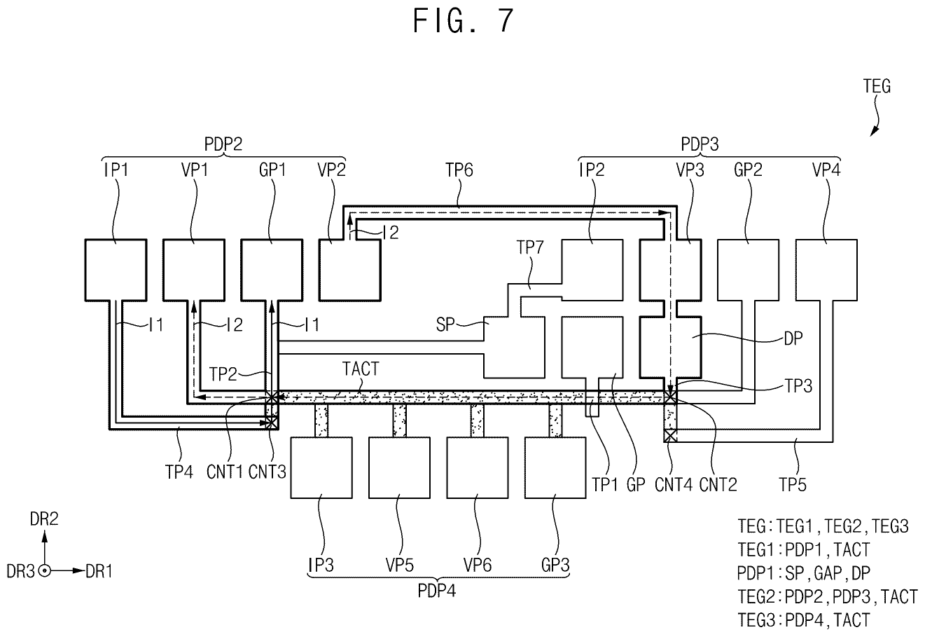

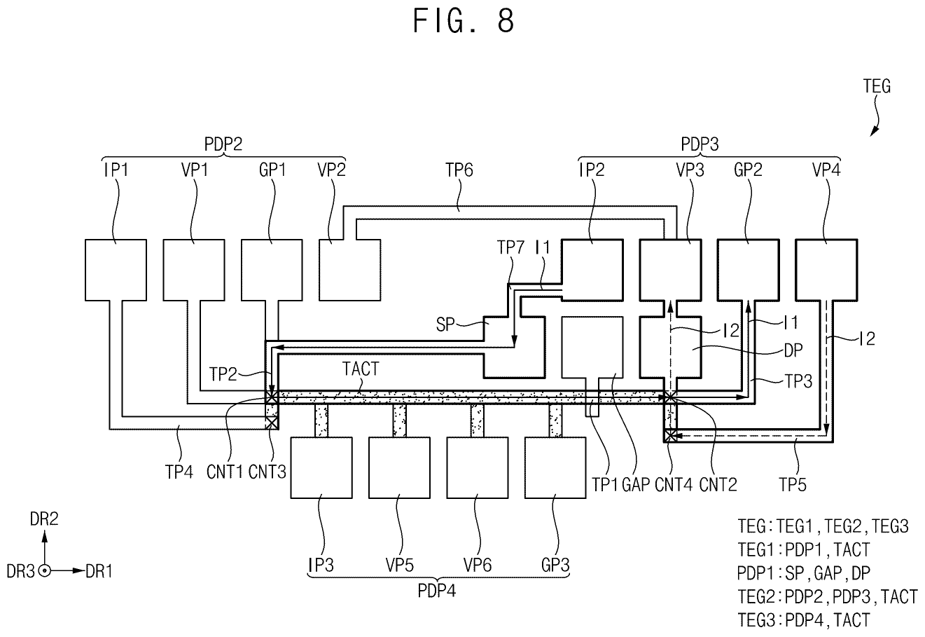

The second test element TEG2 may be used to measure a contact resistance between the pixel active pattern ACT and the pixel output electrode E1 (or E2) of the pixel transistor TFT. A method of measuring the contact resistance using the second test element TEG2 will be described below with reference to FIGS. 7 and 8.

The third test element TEG3 may include a fourth pad portion PDP4 and the test active pattern TACT.

The fourth pad portion PDP4 may include a fifth voltage pad VP5, a sixth voltage pad VP6, a third current pad IP3, and a third ground pad GP3. The third ground pad GP3 may be connected to a ground or receive a ground voltage. In an embodiment, the fourth pad portion PDP4 may be arranged along the first direction DR1. For example, the fourth pad portion PDP4 may be arranged in an order of the third current pad IP3, the fifth voltage pad VP5, the sixth voltage pad VP6, and the third ground pad GP3 along the first direction DR1. However, the present disclosure is not limited thereto.

In an embodiment, the fourth pad portion PDP4, the first pixel output electrode E1, and the second pixel output electrode E2 are arranged in the same layer as each other, and may include the same material as each other. That is, the fifth voltage pad VP5, the sixth voltage pad VP6, the third current pad IP3, the third ground pad GP3, the first pixel output electrode E1, and the second pixel output electrode E2 may be arranged in the same layer as each other, and may include the same material as each other.

The test active pattern TACT may connect the fifth voltage pad VP5, the sixth voltage pad VP6, the third current pad IP3, and the third ground pad GP3. The test active pattern TACT may be arranged under the fifth voltage pad VP5, the sixth voltage pad VP6, the third current pad IP3, and the third ground pad GP3.

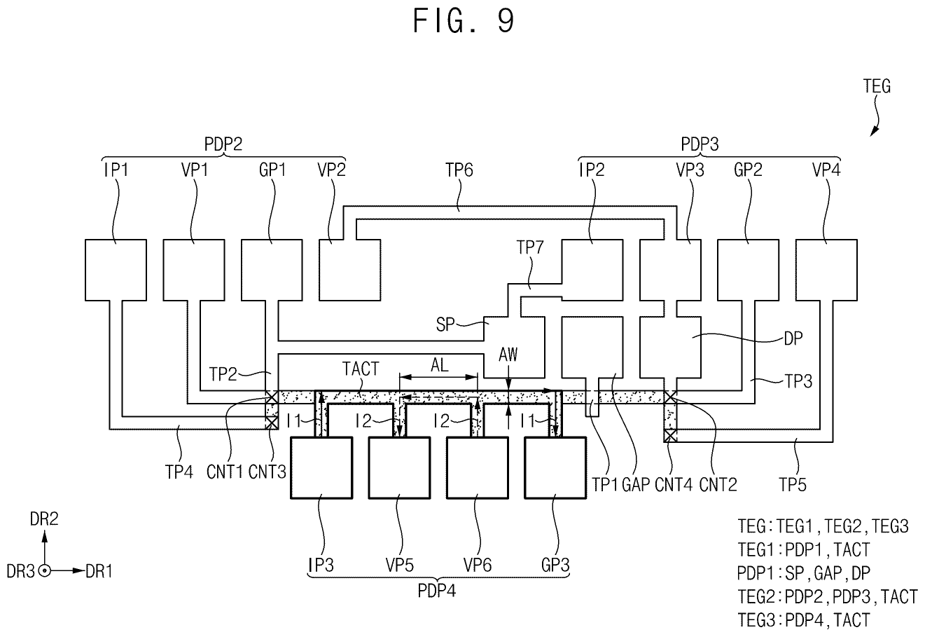

The third test element TEG3 may be used to measure a sheet resistance of the pixel active pattern ACT of the pixel transistor TFT. A method of measuring the sheet resistance by the third test element TEG3 will be described below with reference to FIG. 9.

According to an embodiment, the unit test element TEG includes the first test element TEG1 for testing the characteristics of the pixel transistor TFT, the second test element TEG2 for measuring the contact resistance between the pixel active pattern ACT and the pixel output electrode E1 (or E2), and the third test element TEG3 for measuring the sheet resistance of the pixel active pattern ACT. The first test element TEG1, the second test element TEG2, and the third test element TEG3 may be electrically connected to each other and may share the same test active pattern TACT. However, in an alternate embodiment, the third test element TEG3 is omitted so that only the first test element TEG1 and the second test element TEG2 are present. In another embodiment, the second test element TEG2 is omitted so that only the first test element TEG1 and the third test element TEG3 are present. In yet another embodiment, the first test element TEG1 is omitted so that only the second test element TEG2 and the third test element TEG3 are present.

When the first test element TEG1, the second test element TEG2, and the third test element TEG3 are used to measure parameters using different test active patterns, a problem in which parameters measured in each test element show different tendencies may occur. For example, when a doping process is performed to reduce the resistance of the pixel transistor TFT, a problem may occur in which the current of the pixel transistor TFT is measured as increasing in the first test element TEG1, but the contact resistance is measured as increasing in the second test element TEG2 or the surface resistance is measured as increasing in the third test element TEG3.

According to an embodiment, when the first test element TEG1, the second test element TEG2, and the third test element TEG3 of the unit test element TEG share the same test active pattern TACT, the unit test element TEG may effectively prevent the problem that the parameters measured in each test element shows different tendencies, and may more accurately measure the characteristics of the pixel transistor TFT.

FIGS. 6, 7, 8, and 9 are plan views for describing a method of measuring parameters by the unit test element of FIG. 5 according to an embodiment. For example, FIG. 6 is a plan view for describing a method of testing the characteristics of the pixel transistor TFT using the first test element TEG1. FIG. 7 is a plan view for describing a method of measuring the contact resistance between the pixel active pattern ACT and the pixel output electrode E1 (or E2) using the second pad portion PDP2 of the second test element TEG2. FIG. 8 is a plan view for describing a method of measuring the contact resistance between the pixel active pattern ACT and the pixel output electrode E1 (or E2) using the third pad portion PDP3 of the second test element TEG2. FIG. 9 is a plan view for describing a method of measuring the sheet resistance of the pixel active pattern ACT using the third test element TEG3.

Referring to FIG. 6, the first test element TEG1 may include the test active pattern TACT and the first pad portion PDP1. The first pad portion PDP1 may include the first test pad GAP, the second test pad SP, and the third test pad DP.

The first test pattern TP1 may be connected to the first test pad GAP. The first test pattern TP1 may overlap the test active pattern TACT in a plan view. The first test pattern TP1 may function as the test gate electrode of the test transistor. For example, the first test pattern TP1 may act as the gate electrode in the test transistor structure, controlling its operation just like a gate electrode in a regular thin-film transistor.

The second test pattern TP2 may be connected to the second test pad SP. The second test pattern TP2 may contact the test active pattern TACT through the first contact hole CNT1. The second test pattern TP2 may function as the first test output electrode of the test transistor. For example, the second test pattern TP2 may function as one of the output electrodes (either the source or drain) of the test transistor, enabling external measurement of its electrical characteristics.

The third test pattern TP3 may be connected to the third test pad DP. The third test pattern TP3 may contact the test active pattern TACT through the second contact hole CNT2. The third test pattern TP3 may function as the second test output electrode of the test transistor. For example, the third test pattern TP3 may function as one of the output electrodes (either the source or drain) of the test transistor, enabling external measurement of its electrical characteristics.

Since the test transistor may have the same layered structure as the pixel transistor (TFT, refer to FIG. 3), the characteristics of the pixel transistor TFT may be tested by contacting a test probe to the first test pad GAP, the second test pad SP, and the third test pad DP. That is, by applying a gate on/off voltage to the first test pad GAP and applying various test voltages to the second test pad SP and the third test pad DP through the test probe, various characteristics of the pixel transistor TFT may be tested. For example, the first test element TEG1 may be used to measure a threshold voltage, an off-current or a voltage-current curve of the pixel transistor TFT.

Referring to FIG. 7, the second test element TEG2 may include the second pad portion PDP2, the third pad portion PDP3, and the test active pattern TACT. The second pad portion PDP2 may include the first voltage pad VP1, the second voltage pad VP2, the first current pad IP1, and the first ground pad GP1. The third pad portion PDP3 may include the third voltage pad VP3, the fourth voltage pad VP4, the second current pad IP2, and the second ground pad GP2.

The second test pattern TP2 may be connected to the first voltage pad VP1 and the first ground pad GP1. The second test pattern TP2 may contact the test active pattern TACT through the first contact hole CNT1. The first ground pad GP1 may be connected to ground or receive a ground voltage.

The fourth test pattern TP4 may be connected to the first current pad IP1. The fourth test pattern TP4 may contact the test active pattern TACT through the third contact hole CNT3.

The sixth test pattern TP6 may connect the second voltage pad VP2 and the third voltage pad VP3. The third test pattern TP3 may be electrically connected to the third voltage pad VP3 through the third test pad DP. The third test pattern TP3 may contact the test active pattern TACT through the second contact hole CNT2.

To measure the contact resistance between the pixel active pattern (ACT, refer to FIG. 3) and the pixel output electrode (E1 or E2, refer to FIG. 3) using the second pad portion PDP2, each of a first current I1 and a second current I2 may be applied.

The first current I1 may be supplied from the first current pad IP1 to the first ground pad GP1. Specifically, the first current I1 may flow from the first current pad IP1 to the first ground pad GP1 through the fourth test pattern TP4, the test active pattern TACT, and the second test pattern TP2. This setup may function as if a current source is connected between the first current pad IP1 and the first ground pad GP1, allowing controlled current flow for measurement purposes.

The second current I2 may be supplied from the second voltage pad VP2 to the first voltage pad VP1. Specifically, the second current I2 may flow from the second voltage pad VP2 to the first voltage pad VP1 through the sixth test pattern TP6, the third voltage pad VP3, the third test pad DP, the third test pattern TP3, the test active pattern TACT, and the second test pattern TP2. Accordingly, a voltage between the first voltage pad VP1 and the second voltage pad VP2 may be measured. This setup may function as if a voltage source is connected between the first voltage pad VP1 and the second voltage pad VP2.

The contact resistance may be calculated according to Ohm's law based on the first current I1 and the voltage. Accordingly, the second test element TEG2 may be used to measure the contact resistance between the pixel active pattern and the pixel output electrode.

Referring to FIG. 8, the seventh test pattern TP7 may connect the second current pad IP2 and the second test pad SP. The second test pattern TP2 may be connected to the second test pad SP.

The fifth test pattern TP5 may be connected to the fourth voltage pad VP4. The fifth test pattern TP5 may contact the test active pattern TACT through the fourth contact hole CNT4.

To measure the contact resistance between the pixel active pattern (ACT, refer to FIG. 3) and the pixel output electrode (E1 or E2, refer to FIG. 3) using the third pad portion PDP3, each of a first current I1 and a second current I2 may be supplied.

The first current I1 may be supplied from the second current pad IP2 to the second ground pad GP2. The second ground pad GP2 may be connected to ground or receive a ground voltage. Specifically, the first current I1 may flow from the second current pad IP2 to the second ground pad GP2 through the seventh test pattern TP7, the second test pad SP, the second test pattern TP2, the test active pattern TACT, and the third test pattern TP3. This setup may function as if a current source is connected between the second current pad IP2 and the second ground pad GP2.

The second current I2 may be supplied from the fourth voltage pad VP4 to the third voltage pad VP3. Specifically, the second current I2 may flow from the fourth voltage pad VP4 to the third voltage pad VP3 through the fifth test pattern TP5, the test active pattern TACT, the third test pattern TP3, and the third test pad DP. Accordingly, a voltage between the third voltage pad VP3 and the fourth voltage pad VP4 may be measured. This setup may function as if a voltage source is connected between the third voltage pad VP3 and the fourth voltage pad VP4.

The contact resistance may be calculated according to Ohm's law based on the first current I1 and the voltage. Accordingly, the second test element TEG2 may be used to measure the contact resistance between the pixel active pattern and the pixel output electrode.

Referring to FIG. 9, the third test element TEG3 may include the fourth pad portion PDP4 and the test active pattern TACT. The fourth pad portion PDP4 may include the fifth voltage pad VP5, the sixth voltage pad VP6, the third current pad IP3, and the third ground pad GP3. The test active pattern TACT may connect the fifth voltage pad VP5, the sixth voltage pad VP6, the third current pad IP3, and the third ground pad GP3.

To measure the sheet resistance of the pixel active pattern (ACT, refer to FIG. 3), each of a first current I1 and a second current I2 may be supplied.

The first current I1 may be supplied from the third current pad IP3 to the third ground pad GP3. Specifically, the first current I1 may flow from the third current pad IP3 to the third ground pad GP3 through the test active pattern TACT. This setup may function as if a current source is connected between the third current pad IP3 and the third ground pad GP3.

The second current I2 may be supplied from the sixth voltage pad VP6 to the fifth voltage pad VP5. Specifically, the second current I2 may flow from the sixth voltage pad VP6 to the fifth voltage pad VP5 through the test active pattern TACT. Accordingly, a voltage between the fifth voltage pad VP5 and the sixth voltage pad VP6 may be measured. This setup may function as if a voltage source is connected between the fifth voltage pad VP5 and the sixth voltage pad VP6.

The sheet resistance may be calculated by considering the first current I1, the voltage, a width AW of a measuring portion, and a length AL of the measuring portion. Here, the measuring portion may refer to a portion of the test active pattern TACT where the first current I1 and the second current I2 overlap. Accordingly, the third test element TEG3 may be used to measure the sheet resistance of the pixel active pattern. For example, if the first current I1 is 10 μA and applied to the measuring portion and a voltage of 2 mV is measured across it, the resistance can be calculated using Ohm's Law as R=V/I=(2×10−3 V)/(10×10−6 A)=200 ohms. Assuming the width AW of the measuring portion is 50 μm and the length AL is 200 μm, the sheet resistance is determined using the formula Rs=R×(W/L)=200×( 50/200)=50 ohms per square.

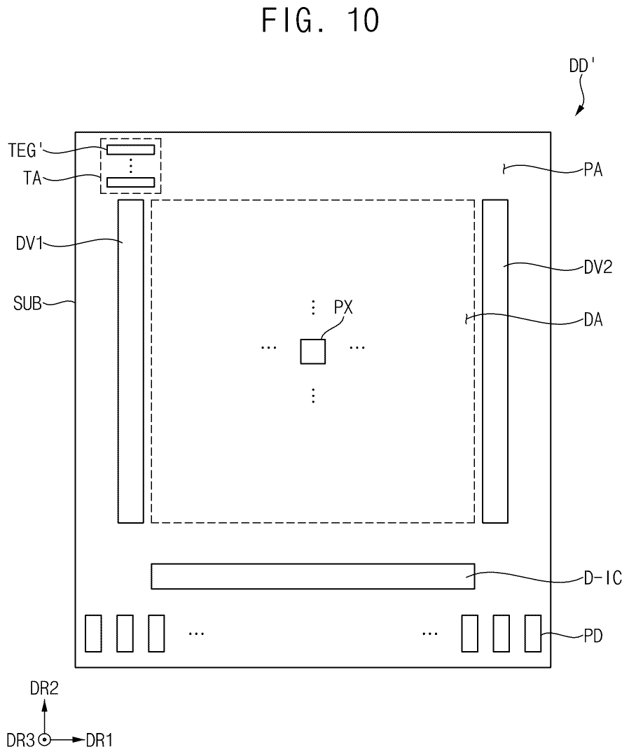

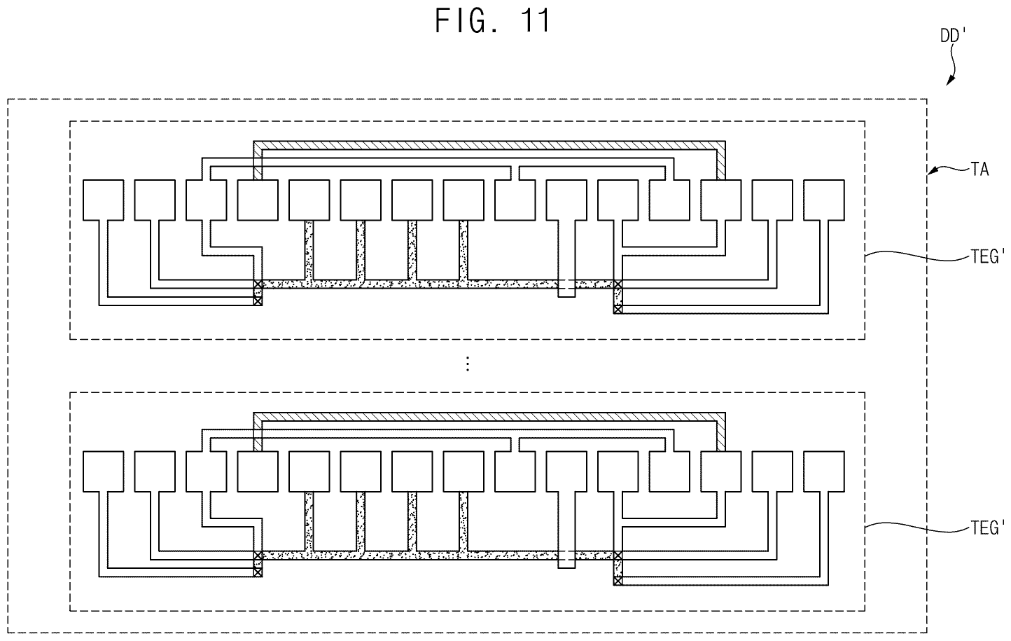

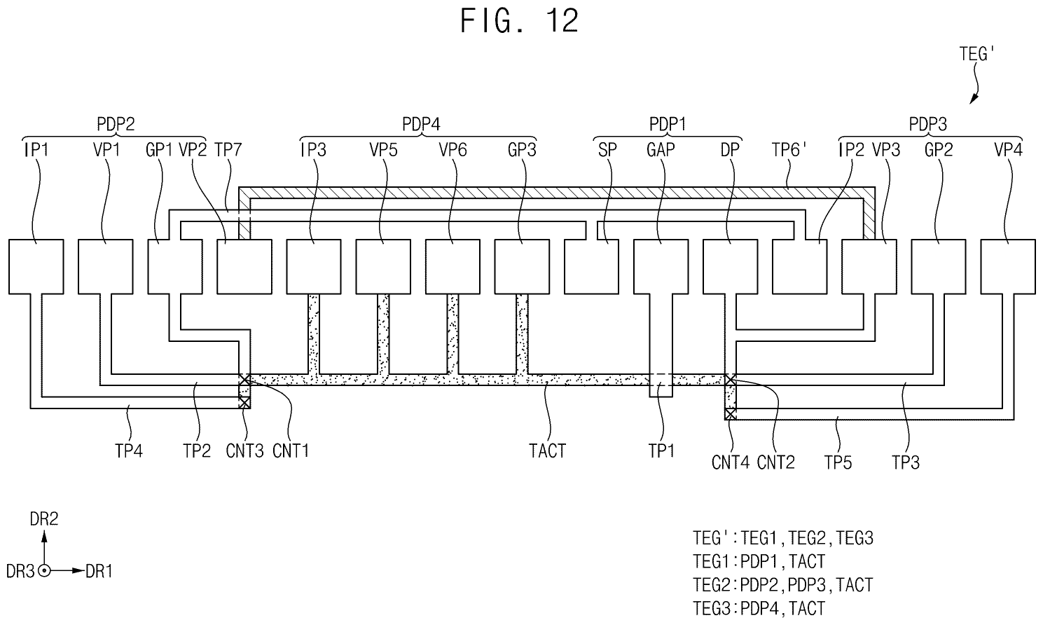

FIG. 10 is a plan view illustrating a display device according to an embodiment of the present disclosure. FIG. 11 is a plan view illustrating a test area of FIG. 10. FIG. 12 is a plan view illustrating a unit test element included the test area in the display device of FIG. 10 according to an embodiment.

Referring to FIGS. 3, 10, 11, and 12, a display device DD′ according to an embodiment of the present disclosure may include a substrate SUB, pixels PX, unit test elements TEG′, a first gate driver DV1, a second gate driver DV2, a driving chip D-IC, and pads PD.

The display device DD′ may be substantially the same as the display device DD described above with reference to FIGS. 1 to 5, except for the planar shape on which first to third test elements TEG1, TEG2, and TEG3 included in the unit test element TEG′ are arranged. Hereinafter, redundant descriptions of the display device DD described above with reference to FIGS. 1 to 5 may be omitted or may be summarized.

The unit test elements TEG′ may be arranged in a test area TA on the substrate SUB. For example, the unit test elements TEG′ may be arranged along the second direction DR2. However, the present disclosure is not limited thereto, and the unit test elements TEG′ may be arranged along the first direction DR1.

As illustrated in FIG. 12, each of the unit test elements TEG′ may include the first test element TEG1, the second test element TEG2, and the third test element TEG3 that are electrically connected to each other. However, in an alternate embodiment, one of the test elements may be omitted. For example, in one embodiment, the first test element TEG1 and the second test element TEG2 are present and the third test element TEG3 is omitted.

The first test element TEG1 may include a test transistor including a test active pattern TACT and a first pad portion PDP1 connected to the test transistor. The first pad portion PDP1 may include a first test pad GAP, a second test pad SP, and a third test pad DP.

The second test element TEG2 may include a second pad portion PDP2, a third pad portion PDP3, and the test active pattern TACT that connects the second pad portion PDP2 and the third pad portion PDP3. The second pad portion PDP2 may include a first voltage pad VP1, a second voltage pad VP2, a first current pad IP1, and a first ground pad GP1. The third pad portion PDP3 may include a third voltage pad VP3, a fourth voltage pad VP4, a second current pad IP2, and a second ground pad GP2.

The third test element TEG3 may include a fourth pad portion PDP4 and the test active pattern TACT. The fourth pad portion PDP4 may include a fifth voltage pad VP5, a sixth voltage pad VP6, a third current pad IP3, and a third ground pad GP3. The test active pattern TACT may connect the fifth voltage pad VP5, the sixth voltage pad VP6, the third current pad IP3, and the third ground pad GP3.

In an embodiment, the first test element TEG1, the second test element TEG2, and the third test element TEG3 are arranged along the first direction DR1. For example, the first to fourth pad portions PDP1, PDP2, PDP3, and PDP4 may be arranged in an order of the second pad portion PDP2, the fourth pad portion PDP4, the first pad portion PDP1, and the third pad portion PDP3 along the first direction DR1. However, the present disclosure is not limited thereto.

In an embodiment, the second pad portion PDP2, the third pad portion PDP3, the fourth pad portion PDP4, the first pixel output electrode E1, and the second pixel output electrode E2 are arranged in the same layer as each other, and may include the same material as each other.

Each of the unit test elements TEG′ may further include first to seventh test patterns TP1, TP2, TP3, TP4, TP5, TP6′, and TP7. In an embodiment, the second test pattern TP2, the third test pattern TP3, the fourth test pattern TP4, the fifth test pattern TP5, the seventh test pattern TP7, the first pixel output electrode E1, and the second pixel output electrode E2 are arranged in the same layer as each other, and may include the same material as each other.

The first test pattern TP1 may be connected to the first test pad GAP. The first test pattern TP1, the first test pad GAP, and the pixel gate electrode GE may be arranged in the same layer as each other, and may include the same material as each other. The first test pattern TP1 may overlap the test active pattern TACT in a plan view. In an embodiment, the first test pattern TP1 may function as a test gate electrode of the test transistor.

The second test pattern TP2 may be connected to the second test pad SP. Specifically, the second test pattern TP2 may be connected to the second test pad SP through the first ground pad GP1 and the seventh test pattern TP7. The second test pattern TP2, the second test pad SP, and the first pixel output electrode E1 may be arranged in the same layer as each other, and may include the same material as each other. The second test pattern TP2 may contact the test active pattern TACT through a first contact hole CNT1. In an embodiment, the second test pattern TP2 may function as a first test output electrode of the test transistor.

The third test pattern TP3 may be connected to the third test pad DP. In an embodiment, the third test pattern TP3, the third test pad DP, and the second pixel output electrode E2 are arranged in the same layer as each other, and may include the same material as each other. The third test pattern TP3 may contact the test active pattern TACT through a second contact hole CNT2. In an embodiment, the third test pattern TP3 may function as a second test output electrode of the test transistor. The test transistor may have the same layered structure as the pixel transistor TFT.

The second test pattern TP2 may be connected to the first voltage pad VP1 and the first ground pad GP1. That is, the second test pattern TP2, which functions as the first test output electrode of the test transistor, may be connected to the first voltage pad VP1 and the first ground pad GP1.

The fourth test pattern TP4 may be connected to the first current pad IP1. The fourth test pattern TP4 may contact the test active pattern TACT through a third contact hole CNT3.

The third test pattern TP3 may be connected to the third voltage pad VP3 and the second ground pad GP2. That is, the third test pattern TP3, which functions as the second test output electrode of the test transistor, may be connected to the third voltage pad VP3 and the second ground pad GP2.

The fifth test pattern TP5 may be connected to the fourth voltage pad VP4. The fifth test pattern TP5 may contact the test active pattern TACT through a fourth contact hole CNT4.

In an embodiment, the sixth test pattern TP6′ may connect the second voltage pad VP2 of the second pad portion PDP2 and the third voltage pad VP3 of the third pad portion PDP3. In an embodiment, the sixth test pattern TP6′ may be arranged under the seventh test pattern TP7. For example, the sixth test pattern TP6′ and the capacitor electrode CAPE may be arranged in the same layer as each other, and may include the same material as each other. However, the present disclosure is not limited thereto.

In an embodiment, the seventh test pattern TP7 may connect the first ground pad GP1 of the second pad portion PDP2 and the second current pad IP2 of the third pad portion PDP3. In addition, the seventh test pattern TP7 may be connected to the second test pad SP. The seventh test pattern TP7 may overlap the sixth test pattern TP6′ in a plan view.

According to the embodiments, the unit test element TEG′ may include the first test element TEG1 for testing the characteristics of the pixel transistor TFT, the second test element TEG2 for measuring a contact resistance between the pixel active pattern ACT and the pixel output electrode E1 (or E2), and the third test element TEG3 for measuring a sheet resistance of the pixel active pattern ACT. The first test element TEG1, the second test element TEG2, and the third test element TEG3 may be electrically connected to each other and may share the same test active pattern TACT. Accordingly, the unit test element TEG′ may effectively prevent the problem that parameters measured in each test element shows different tendencies, and may more accurately measure the characteristics of the pixel transistor TFT. In an alternate embodiment, one of the test elements may be omitted. For example, the first test element TEG1 and the second test element TEG2 may be present while the third test element TEG3 is omitted.

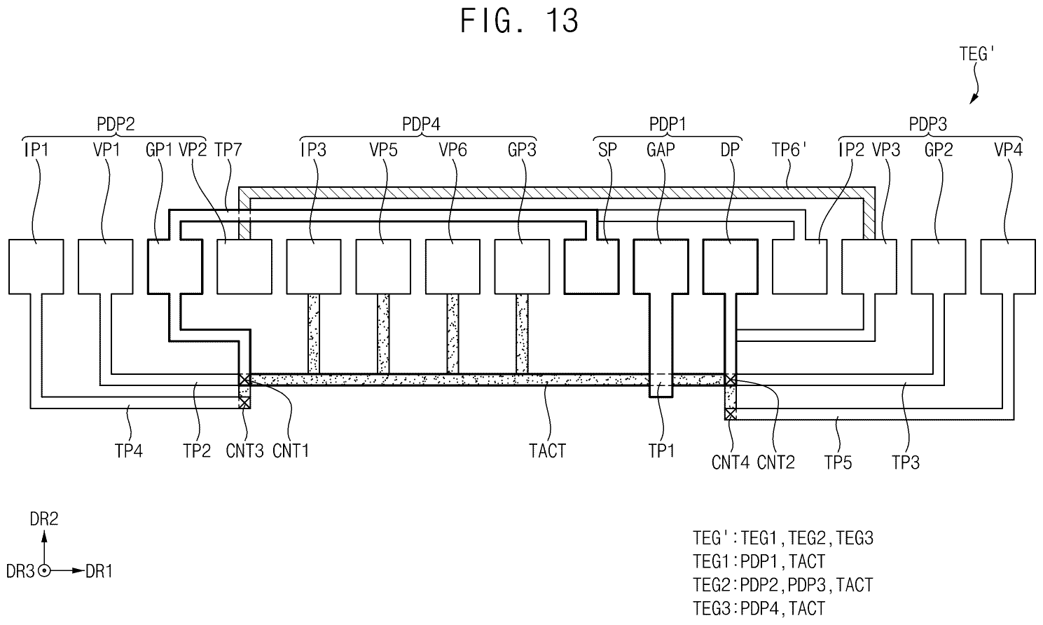

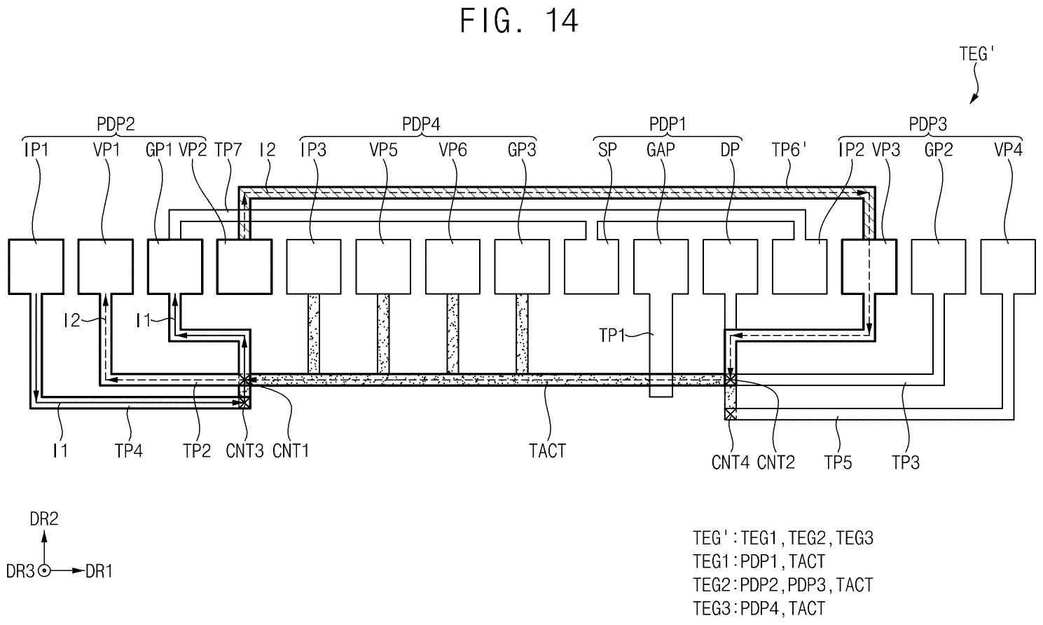

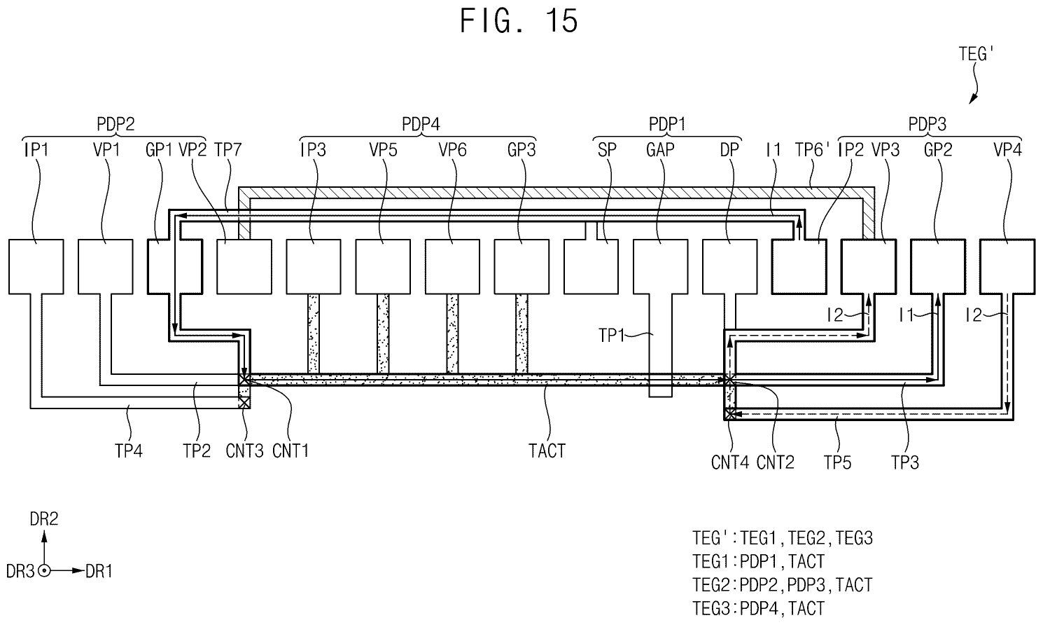

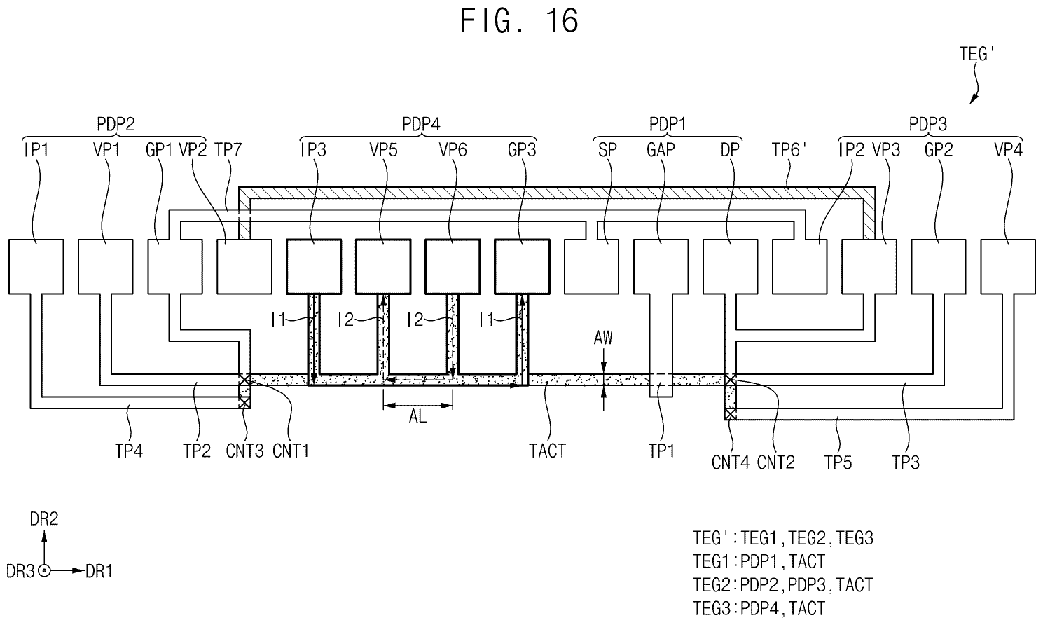

FIGS. 13, 14, 15, and 16 are plan views for describing a method of measuring parameters using the unit test element of FIG. 12. For example, FIG. 13 is a plan view for describing a method of testing the characteristics of the pixel transistor TFT using the first test element TEG1. FIG. 14 is a plan view for describing a method of measuring the contact resistance between the pixel active pattern ACT and the pixel output electrode E1 (or E2) using the second pad portion PDP2 of the second test element TEG2. FIG. 15 is a plan view for describing a method of measuring the contact resistance between the pixel active pattern ACT and the pixel output electrode E1 (or E2) using the third pad portion PDP3 of the second test element TEG2. FIG. 16 is a plan view for describing a method of measuring the sheet resistance of the pixel active pattern ACT using the third test element TEG3.

Referring to FIG. 13, the first test pattern TP1 may be connected to the first test pad GAP and may overlap the test active pattern TACT in a plan view. The first test pattern TP1 may function as the test gate electrode of the test transistor.

The second test pattern TP2 may be connected to the second test pad SP, and may contact the test active pattern TACT through the first contact hole CNT1. The second test pattern TP2 may function as the first test output electrode of the test transistor.

The third test pattern TP3 may be connected to the third test pad DP, and may contact the test active pattern TACT through the second contact hole CNT2. The third test pattern TP3 may function as the second test output electrode of the test transistor.

Since the test transistor may have the same layered structure as the pixel transistor (TFT, refer to FIG. 3), the characteristics of the pixel transistor TFT may be tested by contacting a test probe to the first test pad GAP, the second test pad SP, and the third test pad DP. That is, by applying a gate on/off voltage to the first test pad GAP and applying various test voltages to the second test pad SP and the third test pad DP through the test probe, various characteristics of the pixel transistor TFT may be tested. For example, the first test element TEG1 may be used to test or measure the threshold voltage, the off-current or the voltage-current curve of the pixel transistor TFT.

Referring to FIG. 14, to measure the contact resistance between the pixel active pattern (ACT, refer to FIG. 3) and the pixel output electrode (E1 or E2, refer to FIG. 3) using the second pad portion PDP2, each of a first current I1 and a second current I2 may be supplied.

The first current I1 may be supplied from the first current pad IP1 to the first ground pad GP1. Specifically, the first current I1 may flow from the first current pad IP1 to the first ground pad GP1 through the fourth test pattern TP4, the test active pattern TACT, and the second test pattern TP2. This setup may function as if a current source is connected between the first current pad IP1 and the first ground pad GP1.

The second current I2 may be supplied from the second voltage pad VP2 to the first voltage pad VP1. Specifically, the second current I2 may flow from the second voltage pad VP2 to the first voltage pad VP1 through the sixth test pattern TP6′, the third voltage pad VP3, the third test pattern TP3, the test active pattern TACT, and the second test pattern TP2. Accordingly, a voltage may be measured between the first voltage pad VP1 and the second voltage pad VP2. This setup may function as if a voltage source is connected between the first voltage pad VP1 and the second voltage pad VP2.

The contact resistance may be calculated according to Ohm's law based on the first current I1 and the voltage. Accordingly, the second test element TEG2 may be used to measure the contact resistance between the pixel active pattern and the pixel output electrode.

Referring to FIG. 15, to measure the contact resistance between the pixel active pattern (ACT, refer to FIG. 3) and the pixel output electrode (E1 or E2, refer to FIG. 3) using the third pad portion PDP3, each of a first current I1 and a second current I2 may be supplied.

The first current I1 may be supplied from the second current pad IP2 to the second ground pad GP2. Specifically, the first current I1 may flow from the second current pad IP2 to the second ground pad GP2 through the seventh test pattern TP7, the first ground pad GP1, the second test pattern TP2, the test active pattern TACT, and the third test pattern TP3. This setup may function as if a current source being connected between the second current pad IP2 and the second ground pad GP2.

The second current I2 may be supplied from the fourth voltage pad VP4 to the third voltage pad VP3. Specifically, the second current I2 may flow from the fourth voltage pad VP4 to the third voltage pad VP3 through the fifth test pattern TP5, the test active pattern TACT, and the third test pattern TP3. Accordingly, a voltage between the third voltage pad VP3 and the fourth voltage pad VP4 may be measured. This setup may function as if a voltage source is connected between the third voltage pad VP3 and the fourth voltage pad VP4.

The contact resistance may be calculated according to Ohm's law based on the first current I1 and the voltage. Accordingly, the second test element TEG2 may be used to measure the contact resistance between the pixel active pattern and the pixel output electrode.

Referring to FIG. 16, to measure the sheet resistance of the pixel active pattern (ACT, refer to FIG. 3), each of a first current I1 and a second current I2 may be supplied.

The first current I1 may be supplied from the third current pad IP3 to the third ground pad GP3. Specifically, the first current I1 may flow from the third current pad IP3 to the third ground pad GP3 through the test active pattern TACT. This setup may function as if a current source is connected between the third current pad IP3 and the third ground pad GP3.

The second current I2 may be supplied from the sixth voltage pad VP6 to the fifth voltage pad VP5. Specifically, the second current I2 may flow from the sixth voltage pad VP6 to the fifth voltage pad VP5 through the test active pattern TACT. Accordingly, a voltage between the fifth voltage pad VP5 and the sixth voltage pad VP6 may be measured. This setup may function as if a voltage source is connected between the fifth voltage pad VP5 and the sixth voltage pad VP6.

The sheet resistance may be calculated by considering the first current I1, the voltage, a width AW of a measuring portion, and a length AL of the measuring portion. Here, the measuring portion may refer to a portion of the test active pattern TACT where the first current I1 and the second current I2 overlap. Accordingly, the third test element TEG3 may be used to measure the sheet resistance of the pixel active pattern.

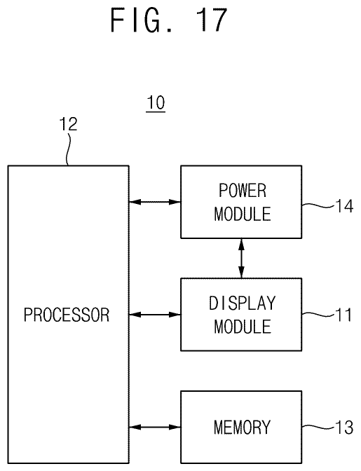

FIG. 17 is a block diagram of an electronic device according to an embodiment of the present disclosure.

Referring to FIG. 17, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

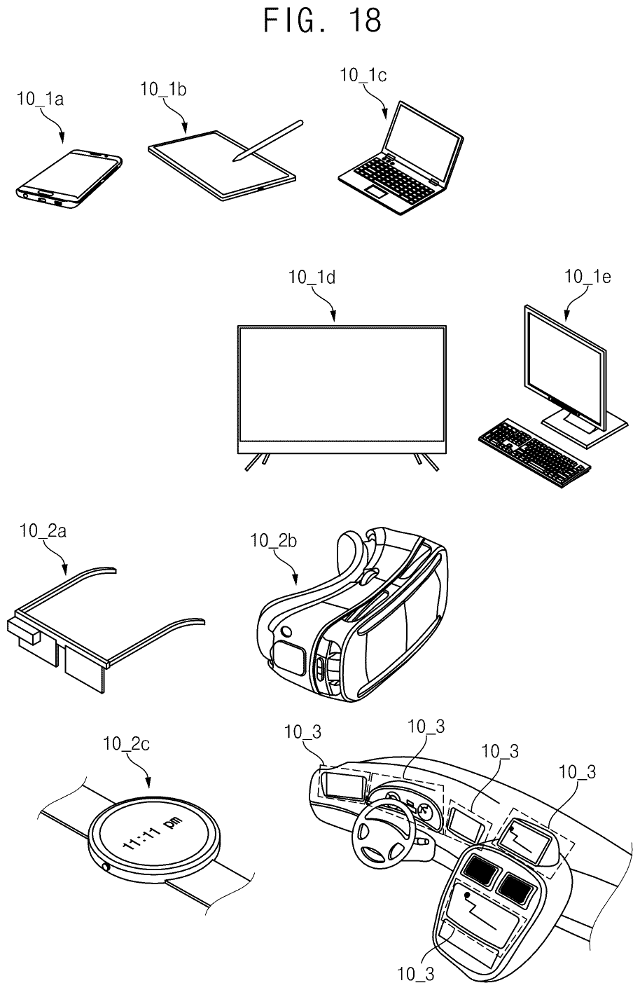

FIG. 18 is a schematic diagram of an electronic device according to various embodiments.

Referring to FIG. 18, various electronic devices to which a display device according to the embodiments is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on an instrument panel, a center fascia, and a dashboard of an automobile and a room mirror display, or the like.

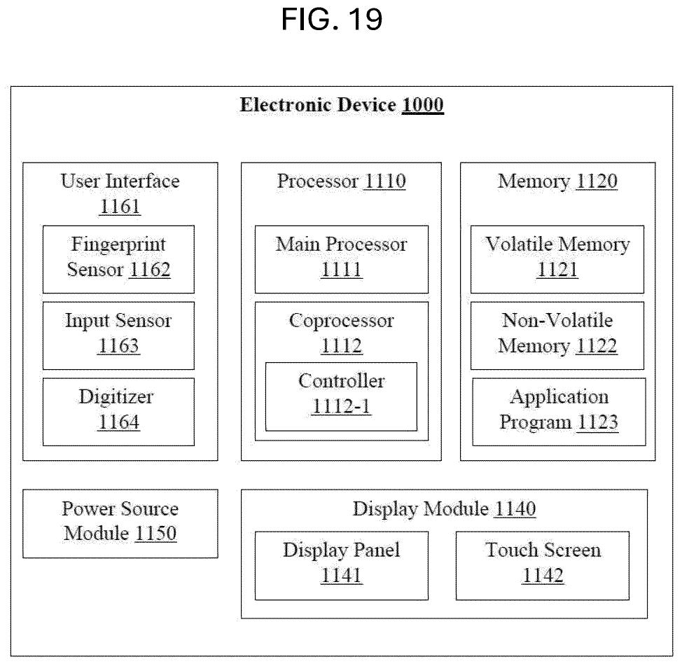

FIG. 19 is a diagram illustrating an electronic device according to an embodiment of the present invention. Referring to FIG. 19, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141. The processor 1110 may be used to implement processor 12. The memory 1120 may be used to implement the memory device 13.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 may be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display module 1140 may be used to implement the display device 1060. The display panel 1141 may include the display unit shown in FIG. 1.

The power source module 1150 may supply power to the components of the electronic device 1000. The power source module 1150 may be used to implement the power supply 1050. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure.

What is claimed is:

1. A display device comprising:
a substrate comprising a display area and a test area located adjacent the display area;
a pixel arranged in the display area on the substrate and comprising a pixel transistor and a light-emitting element connected to the pixel transistor; and
a unit test element arranged in the test area on the substrate and comprising a test active pattern,
wherein the unit test element comprises:
a first test element comprising a test transistor which comprises the test active pattern, and a first pad portion which comprises test pads connected to the test transistor;
a second test element comprising a second pad portion which comprises a first voltage pad, a second voltage pad, a first current pad, and a first ground pad, a third pad portion which comprises a third voltage pad, a fourth voltage pad, a second current pad, and a second ground pad, wherein the second pad portion and the third pad portion are connected to the test active pattern; and
a third test element comprising a fourth pad portion which comprises a fifth voltage pad, a sixth voltage pad, a third current pad, and a third ground pad, wherein the fifth voltage pad, the sixth voltage pad, the third current pad, and the third ground pad are connected to the test active pattern.

2. The display device of claim 1, wherein the first test element, the second test element, and the third test element are electrically connected to each other.

3. The display device of claim 1, wherein the pixel transistor comprises:
a pixel active pattern;
a pixel gate electrode overlapping the pixel active pattern in a plan view;
a first pixel output electrode connected to the pixel active pattern; and
a second pixel output electrode connected to the pixel active pattern, and
wherein the test active pattern and the pixel active pattern are arranged in a same layer as each other, and comprise a same material as each other.

4. The display device of claim 3, wherein the second pad portion, the third pad portion, the fourth pad portion, the first pixel output electrode, and the second pixel output electrode are arranged in a same layer as each other, and comprise a same material as each other.

5. The display device of claim 3, wherein the first pad portion comprises:
a first test pad arranged in a same layer and comprising a same material as the pixel gate electrode;
a second test pad arranged in a same layer and comprising a same material as the first pixel output electrode; and
a third test pad arranged in a same layer and comprising a same material as the second pixel output electrode.

6. The display device of claim 5, wherein the unit test element further comprises:
a first test pattern connected to the first test pad and overlapping the test active pattern in the plan view;
a second test pattern connected to the first voltage pad and the test active pattern;
a third test pattern connected to the second ground pad and the test active pattern;
a fourth test pattern connected to the first current pad and the test active pattern; and
a fifth test pattern connected to the fourth voltage pad and the test active pattern.

7. The display device of claim 6, wherein the second test pattern, the third test pattern, the fourth test pattern, the fifth test pattern, the first pixel output electrode, and the second pixel output electrode are arranged in a same layer as each other, and comprise a same material as each other.

8. The display device of claim 6, wherein the first test pattern functions as a test gate electrode of the test transistor.

9. The display device of claim 6,
wherein the second test pattern functions as a first test output electrode of the test transistor, and
wherein the third test pattern functions as a second test output electrode of the test transistor.

10. The display device of claim 6, wherein the unit test element further comprises a sixth test pattern which connects the second voltage pad and the third voltage pad.

11. The display device of claim 10, wherein the sixth test pattern, the first pixel output electrode, and the second pixel output electrode are arranged in a same layer as each other, and comprise a same material as each other.

12. The display device of claim 10,
wherein the unit test element further comprises a seventh test pattern which connects the first ground pad and the second current pad, and overlaps the sixth test pattern in the plan view,
wherein the seventh test pattern, the first pixel output electrode, and the second pixel output electrode are arranged in a same layer as each other, and comprise a same material as each other, and
wherein the sixth test pattern is arranged under the seventh test pattern.

13. The display device of claim 10, wherein when measuring a parameter using the second test element,
a first current flows from the first current pad to the first ground pad through the fourth test pattern, the test active pattern, and the second test pattern, and
a second current flows from the second voltage pad to the first voltage pad through the sixth test pattern, the third voltage pad, the third test pattern, the test active pattern, and the second test pattern.

14. The display device of claim 10, wherein when measuring a parameter using the second test element,
a first current flows from the second current pad to the second ground pad through the second test pattern, the test active pattern, and the third test pattern, and
a second current flows from the fourth voltage pad to the third voltage pad through the fifth test pattern, the test active pattern, and the third test pattern.

15. The display device of claim 1, wherein when measuring a parameter using the third test element,
a first current flows from the third current pad to the third ground pad through the test active pattern, and
a second current flows from the sixth voltage pad to the fifth voltage pad through the test active pattern.

16. The display device of claim 1,
wherein the test pads are arranged along a first direction,
wherein the first voltage pad, the second voltage pad, the first current pad, and the first ground pad are arranged along the first direction,
wherein the third voltage pad, the fourth voltage pad, the second current pad, and the second ground pad are arranged along the first direction, and
wherein the fifth voltage pad, the sixth voltage pad, the third current pad, and the third ground pad are arranged along the first direction.

17. The display device of claim 16, wherein the first test element, the second test element, and the third test element are arranged along a second direction intersecting the first direction.

18. The display device of claim 16, wherein the first test element, the second test element, and the third test element are arranged along the first direction.

19. A display device comprising:
a substrate comprising a display area and a test area located adjacent the display area;
a pixel arranged in the display area on the substrate and comprising a pixel transistor and a light-emitting element connected to the pixel transistor; and
a unit test element arranged in the test area on the substrate and comprising a test active pattern,
wherein the unit test element comprises:
a first test element comprising a test transistor which comprises the test active pattern, and a first pad portion which comprises test pads connected to the test transistor to enable measurement of characteristics of the pixel transistor; and
a second test element comprising a second pad portion which comprises a first voltage pad, a second voltage pad, a first current pad, and a first ground pad, a third pad portion which comprises a third voltage pad, a fourth voltage pad, a second current pad, and a second ground pad, wherein the second pad portion and the third pad portion are connected to the test active pattern to enable measurement of a contact resistance between a pixel active pattern and a pixel output electrode of the pixel transistor.

20. An electronic device comprising:
a display device comprising a pixel; and
a processor which transmits an image data signal and an input control signal to the display device,
wherein the display device comprises:
a substrate comprising a display area and a test area located adjacent the display area;
the pixel arranged in the display area on the substrate and comprising a pixel transistor and a light-emitting element connected to the pixel transistor; and
a unit test element arranged in the test area on the substrate and comprising a test active pattern, and
wherein the unit test element comprises:
a first test element comprising a test transistor which comprises the test active pattern, and a first pad portion which comprises test pads connected to the test transistor;
a second test element comprising a second pad portion which comprises a first voltage pad, a second voltage pad, a first current pad, and a first ground pad, a third pad portion which comprises a third voltage pad, a fourth voltage pad, a second current pad, and a second ground pad, wherein the second pad portion and the third pad portion are connected to the test active pattern; and
a third test element comprising a fourth pad portion which comprises a fifth voltage pad, a sixth voltage pad, a third current pad, and a third ground pad, wherein the fifth voltage pad, the sixth voltage pad, the third current pad, and the third ground pad are connected to the test active pattern.
